(19) United States
(12) Patent Application Publication
(10) Pub. No.: US 2002/0192569 A1
(43) Pub. Date: Dec. 19, 2002

(54) Devices and methods for exposure of photoreactive compositions with light emitting diodes

(75) Inventors: William Charles Ulland, Duluth, MN (US); Alexander Sergeievich Gybin, Duluth, MN (US); Toshifumi Komatsu, Duluth, MN (US); Claude P.A. Piguet, Cotton, MN (US)

Correspondence Address: MERCHANT & GOULD PC, P.O. BOX 2903, MINNEAPOLIS, MN, 55402-0903, US

(73) Assignee: The Chromaline Corporation

(21) Appl. No.: 09/858,272

(22) Filed: May 15, 2001

(51) Int. Cl. G03F 9/00; G02F 1/01; G02B 26/00

(52) U.S. Cl. 430/5; 430/7; 359/238

(57) ABSTRACT

The present invention is directed to devices and methods for exposing photoreactive compositions. Specifically, the invention is directed to devices and methods for exposing photoreactive compositions with light from light emitting diodes (LEDs). In certain embodiments the device includes an apparatus for retaining a photosensitive substrate containing a photoreactive composition, a light emitting diode array containing a plurality of light emitting diodes, and a control mechanism for regulating the intensity and distribution of light emitted from the light emitting diode array. In such implementations the light emitting diodes are configured and arranged for controlled exposure of the photoreactive composition.

### FIELD OF THE INVENTION

The present invention is directed to devices and methods for exposing photoreactive compositions. More specifically, the invention is directed to devices and methods for exposing photoreactive compositions, such as those used in screen printing, with light emitting diodes.

### BACKGROUND OF THE INVENTION

Photosensitive laminates have been used for years to create imageable patterns useful for screen-printing and abrasion etching of substrate materials. The laminates contain photoreactive materials that are sensitive to light. Light is used to imagewise expose these laminates and form a durable image in the laminate structure. Thereafter, the laminate structure can be used for screen printing, abrasive etching, chemical etching, or other specific applications.

Although such imagewise exposure methods are suitable for many uses, they have certain limitations. Imagewise exposure methods usually require the use of traditional negatives or masks to control which portions of the substrate are exposed to light. These negatives or masks require time, effort, and materials to prepare, and thus are not well suited to applications where immediate image exposure is desired. They also require the lights to pass through another material for exposure, normally glass with a vacuum frame, which can further reduce the energy reaching the substrate. In addition, these traditional methods lack the ability to efficiently transfer images from a digital file (such as an image drafted in a graphic imaging software application) onto an exposed substrate.

Thus, a need exists for improved devices and methods that allow rapid, high-quality, and inexpensive exposure of photosensitive structures containing photoreactive materials (such as photoreactive resins), particularly without the use of a negative or mask.

### SUMMARY OF THE INVENTION

The present invention is directed to devices and methods for exposing photoreactive compositions. Specifically, the invention is directed to devices and methods for exposing photoreactive compositions with radiation from light emitting diodes (LEDs). In certain embodiments the device includes an apparatus for retaining a photosensitive substrate containing a photoreactive resin composition, a light emitting diode array containing a plurality of light emitting diodes, and a control mechanism for regulating the quantity and distribution of light emitted from the light emitting diode array. The control mechanism typically regulates the position of the LEDs relative to the substrate, and also controls turning the LEDs on and off in order to precisely regulate which portions of the substrate are exposed to light emitted from the LEDs. In such implementations the light emitting diodes are usually configured and arranged for accurate exposure of the photoreactive composition by being independently controlled to move relative to the substrate.

The photoreactive compositions of the invention are typically relatively thick films (usually greater than 20 microns thick) that react to light in a manner such that their physical strength is significantly increased by exposure to light of specific wavelengths. This transformation in physical properties makes the photoreactive compositions, which are usually resins, well suited for screen printing and abrasive etching of images. In implementations where the photoreactive composition is strengthened upon exposure to light (such as by crosslinking), the unexposed composition can be removed to create a suitable printing screen containing only the exposed composition.

LEDs for use with the present invention typically have significant emission levels of light having wavelengths below 450 nm, and even more typically below 430 nm. The wavelength or wavelengths of light are selected such that they sufficiently react with and penetrate into the photoreactive composition. These compositions are typically most reactive to light below 450 nm, and thus the wavelength of light emitted by the LEDs is typically predominantly below 450 nm. In addition, some such LEDs show multiple ranges of high intensity radiation below 430 nm. Such LEDs are particularly well suited to the present invention because they allow curing of photoreactive compositions that are sensitive to more than one wavelength of light.

Not only should the LEDs have a satisfactory wavelength of light, but they must also provide sufficiently intense radiation to permit a thorough reaction in the photoreactive composition. Due to the relatively thick nature of the photoreactive compositions, it is usually necessary to apply at least 50 mJ/cm², more typically at least 75 mJ/cm² of photoreactive composition, and even more typically greater than 100 mJ/cm².

The LEDs of the present invention are generally configured in an array to provide high-speed, high-definition exposure of the photoreactive composition. The array can be, for example, a matrix containing multiple independently controlled LEDs. By controlling the duration of light emitted from each LED it is possible to control the amount of curing in the photoreactive composition at specific portions of the photosensitive substrate, thereby forming a precise image on the substrate.

The array of LEDs can be positioned such that they directly expose the photoreactive composition. Such exposure is advantageous because it avoids absorption of emitted light by intervening material. However, more typically, the LEDs are configured such that emitted light is guided to the photoreactive composition by a light guide, such as a fiber optic cable or other reflective device. The light guide can serve to focus the light from the LEDs onto smaller areas than would otherwise be possible. The light guide preferably has little or no significant absorption in the wavelengths absorbed by the substrate.

The present invention is also directed to methods of exposing a substrate containing a photoreactive composition. The methods generally include providing a light emitting device for controlled exposure of photoreactive compositions, the device comprising an apparatus for retaining a photosensitive substrate containing a photoreactive composition; a light emitting diode array containing a plurality of light emitting diodes; and a control mechanism for regulating the quantity and distribution of light emitted from the light emitting diode array. The light emitting diodes are configured and arranged for controlled exposure of the photoreactive composition. A substrate containing a photoreactive composition is provided; and this substrate is exposed with light from the light emitting device to create an image.

Other features and advantages of the invention will be apparent from the following detailed description of the invention and the claims. The above summary of principles of the disclosure is not intended to describe each illustrated embodiment or every implementation of the present disclosure. The detailed description that follows more particularly exemplifies certain embodiments utilizing the principles disclosed herein.

### DRAWINGS

The invention will be more fully explained with reference to the following drawings, in which:

FIG. 1 is a schematic diagram of a device constructed and arranged in accordance with the present invention.

FIG. 2 is a schematic diagram of a device constructed and arranged in accordance with the present invention.

FIG. 3A is a top plan view of a first array of LEDs constructed and arranged in accordance with the present invention.

FIG. 3B is a top plan view of a second array of LEDs constructed and arranged in accordance with the present invention.

FIG. 3C is a top plan view of a third array of LEDs constructed and arranged in accordance with the present invention.

While principles of the invention are amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the disclosure.

### DETAILED DESCRIPTION OF THE INVENTION

The present invention is directed to devices and methods for exposing photoreactive compositions with light from light emitting diodes (LEDs). In certain embodiments the device includes an apparatus for retaining a photosensitive substrate containing a photoreactive composition, a light emitting diode array containing a plurality of light emitting diodes, and a control mechanism for regulating the intensity and distribution of light emitted from the light emitting diode array. In such implementations the light emitting diodes are configured and arranged for controlled exposure of the photoreactive composition.

A detailed description of specific embodiments of the invention will now be provided, including a system overview, a discussion of suitable light emitting diodes, arrays of light emitting diodes, use of light guides, suitable substrates, methods, and experimental data. It will be appreciated that the following discussion is provided for illustrative purposes, and that the invention is not constrained by this discussion but rather is intended to have the full breadth of the claims provided herein.

A. LED Exposure Device

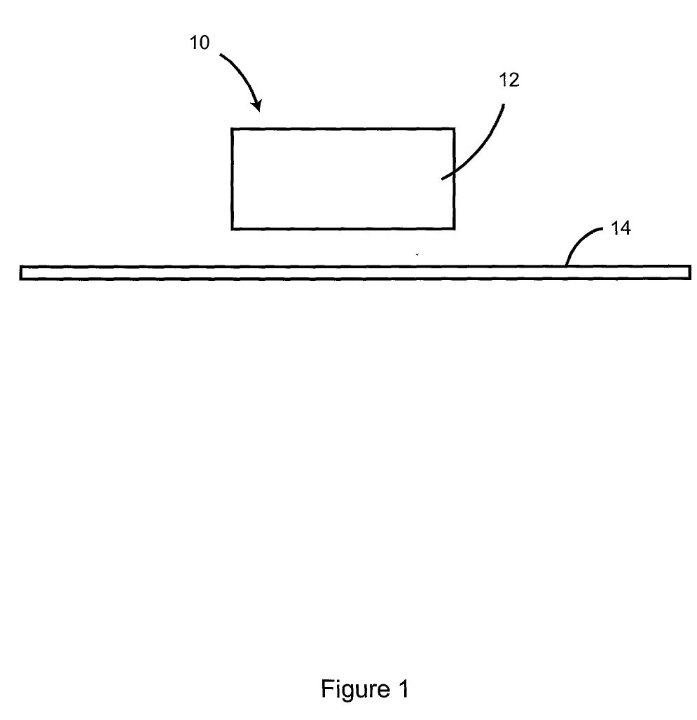

The present invention is directed to devices and methods for exposing photoresist substrates containing a photoreactive composition with light from LEDs, in particular LEDs having a significant emission of light at wavelengths below 450 nanometers (nm). A schematic diagram of a basic device suitable for performing the methods of the invention is depicted in FIG. 1. Device 10 is depicted with an LED light source 12 and a substrate 14. The LED light source 10 provides controlled illumination of portions of the substrate 14 with light of sufficient intensity, wavelength, and duration to produce a desired image on the substrate. The image can subsequently be revealed by further processing of the substrate. After this further processing the image is suitable for use in various processes, such as screen printing, chemical etching, or particulate etching.

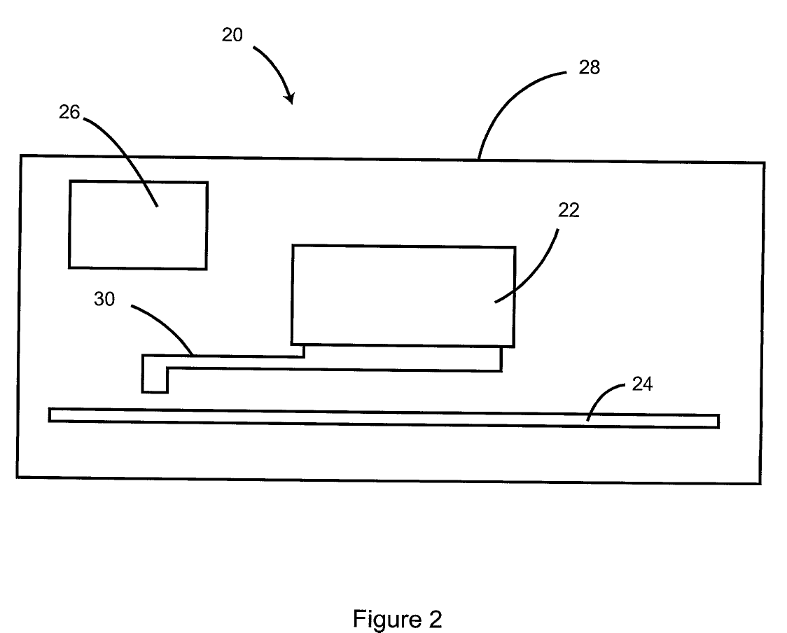

An enhanced device constructed in accordance with the invention is depicted schematically in FIG. 2. Device 20 contains LED light source 22 and substrate 24. However, a computer or control module 26 is further identified, as is a generalized movement mechanism 28 for moving the substrate and LED light source 22 with respect to one another, and light guide 30. The LED light source 22 typically contains a plurality of light emitting diodes arranged in an array. The substrate 24 generally contains a photoreactive composition. As used herein, photoreactive compositions are compositions that undergo a transformation upon exposure to light making the compositions substantially stronger or weaker than compositions that have not been exposed to light. For example, the photoreactive composition can undergo crosslinking to become more durable. In this manner, the photoresist compositions undergo sufficient physical changes to make them suitable imaging compositions for screen printing or particulate etching.

The computer or control module 26 provides coordination between the various components, and in particular can regulate the quantity or duration of light emitted by the various LEDs of LED light source 22, and as such controls the exposure of the photoreactive composition in the substrate 24. Control module 26 can comprise a personal computer (PC), workstation or other independent device. Alternatively, the control module 26 can be integrated into the device 20.

In addition, control module 26 can regulate the relative position of the LED light source 22 and the substrate 24 by moving the light source 22 or the substrate 24 (or both) in order to expose large portions of the substrate 24 with light from light source 22. The actual movement is provided by mechanism 28, which is generalized and shown only in schematic form in FIG. 2. Movement mechanism 28 can include, for example, an apparatus for moving the LED light source 22 in a pattern across the exposed surface of the substrate 24. Alternatively, the light source 22 can remain stationary and the substrate 24 can be moved.

In certain embodiments of the invention a light guide 30 is used to direct light from the LEDs in the light source 22 onto the substrate 24. The light guide can include, for example, lenses, mirrors, optical fibers or combinations thereof that direct light from individual LEDs in the light source onto the substrate 24. The light guide's functions can be limited to focusing the light from the LEDs into a smaller area to create a finer resolution of the imaging process, or can include guiding light to areas of the substrate 24 that are physically distant from the LED light source 22 by using fiber optics. In such implementations the ends of the fiber optics can be moved relative to the substrate 24 in order to expose portions of the entire substrate without moving the LED light source 22 or the substrate 24 present.

Certain embodiments also include methods for calibrating the intensity of each LED as well as checking to see if all LEDs are properly functioning. The invention can also include devices and methods for detecting the presence of a substrate, as well as the type of substrate.

B. Light Emitting Diodes

The present invention uses light emitting diodes (LEDs) to expose photoreactive compositions. The light-emitting diodes typically comprise a p-n junction in which an applied voltage yields a flow of current, and the recombination of the carriers injected across the junction results in the emission of light. The LEDs used with the present invention are generally selected to have high emission spectra in wavelengths that correspond to the absorption spectra of the photoreactive compositions. The LEDs typically have significant emission levels of light having wavelengths below 450 nm, and even more typically below 430 nm. Particularly useful ranges of emission include 300 to 450 nm. Additional useful ranges include 390 to 450 nm and 350 to 430 nm. LEDs having strong emission spectra at approximately 370, 380 and/or 390 nm are useful in various implementations of the invention.

Generally, the LEDs have strong emission spectra below 450 nm, but they can also have some emission spectra with wavelengths greater than 450 nm. However, such longer wavelength light is generally less desirable because the photoreactive resins do not generally strongly react to light of wavelengths greater than 450 nm. In most implementations, the LEDs of the invention have greater than 80% of their emission spectra at wavelengths below 450 nm.

In addition, some LEDs suitable for use with the invention show multiple ranges of high intensity radiation below 450 nm. Such LEDs are particularly well suited to the present invention because they allow curing of photoreactive compositions that are sensitive to more than one wavelength of light below 450 nm. These LEDs are unique in that they provide relatively high intensity light at more than one wavelength range. Depending upon the LED used, the light can have a constant spectral distribution or, alternatively, have a changing spectral distribution depending upon the voltage of applied electric current. LEDs having this characteristic change in spectral distribution are particularly useful for applications where more than one photoreactive composition is present and the photoreactive compositions are sensitive to different wavelengths of light. By using an LED with changeable spectral distribution, each of the photoreactive compositions can be selectively reacted.

C. LED Arrays

The LEDs of the present invention are generally configured in an array to provide high-speed, high-definition exposure of the photoreactive composition in the substrate. Suitable arrays can be, for example, a matrix containing multiple independently controlled LEDs. The LEDs can all emit substantially the same wavelengths of light, or alternatively the LEDs can be of two or more types that have different spectrums of light emission. By controlling the wavelength or duration of light emitted from each LED it is possible to significantly control the amount of curing in various portions of the photoreactive composition. Arrays of LEDs are particularly well suited to applications where only a portion of the photoreactive composition is to be exposed, or where portions of the photoreactive composition are to be differentially exposed.

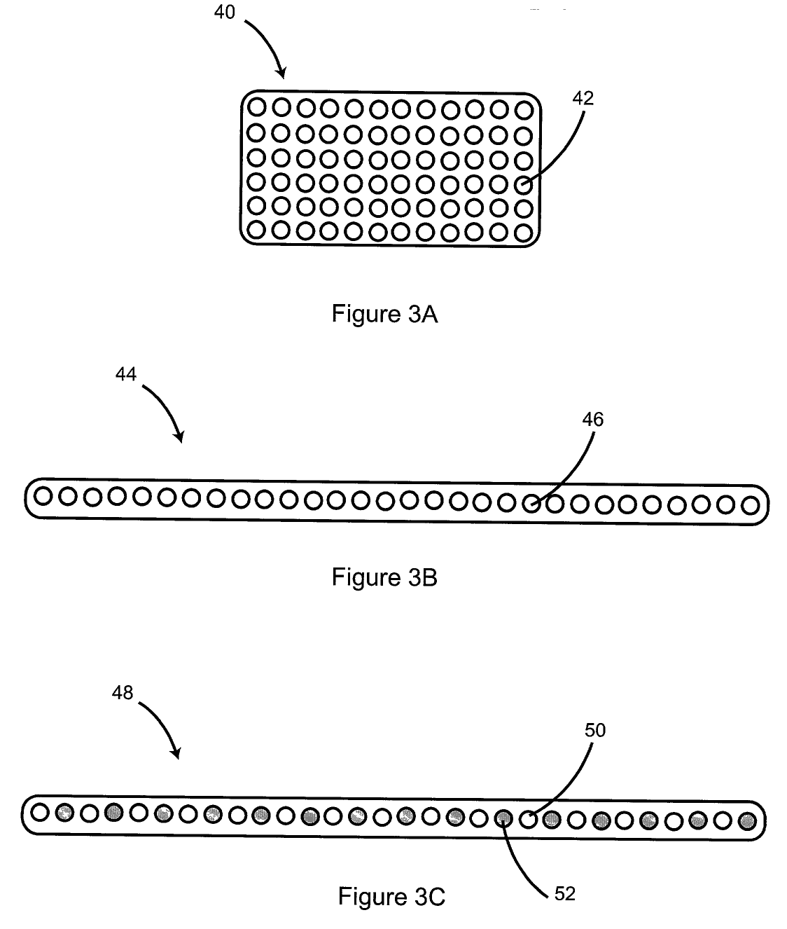

A first example array of LEDs is depicted in FIG. 3A. The array 40 contains multiple LEDs 42. Each LED 42 is normally independently controlled, and thus the time, intensity and duration at which each LED is turned on is independent of neighboring LEDs. The array 42 is generally rectangular, containing multiple columns and rows. An alternative configuration is shown in FIG. 3B in which array 44 has a single row of LEDs 46. Array 44 is particularly well suited to single-pass exposure of a substrate when the array 44 has a length corresponding to the width of an image to be exposed. By moving the array 44 across the substrate and cycling the LEDs 46 on and off, the entire substrate can be imaged in one pass. Such methods are suitable, for example, for sheet-feed processing of the substrate in a device constructed in accordance with the invention. An alternative array is shown in FIG. 3C, where array 48 has two types of alternate LEDs 50, 52. The two types of LEDs 50, 52 have different emission spectra and are thus well suited to exposure of multiple photoreactive resins or to photoreactive resins that are sensitive to more than one wavelength of light.

D. Light Guides

The array of LEDs can be positioned such that they directly expose the photoreactive composition. However, more typically, the LEDs are configured such that their emitted light is guided to the photoreactive composition by a light guide, such as a fiber optic cable or other reflective device. Light guides can provide a variety of advantages, including narrowing the light from specific LEDs such that the light is focused on a smaller surface area than the actual surface size of the LED itself. Such focusing allows for finer detail to be imaged as well as permitting more intense light, which is often necessary in order to adequately expose the photoreactive resin.

A suitable light guide for use with the present invention includes one or more lenses configured to focus the light from each LED onto the substrate. In certain implementations the LEDs are larger than the desired exposure resolution, and therefore some diminishment in the effective LED size is desirable, which can be accomplished using lenses. These implementations typically comprise a convex lens positioned between each of the exposed LEDs and the substrate.

An alternative suitable light guide for use with the present invention includes various reflective elements, including internal reflectors or total internal reflectors that function by reflecting light along interfaces having a high difference in index of refraction. Various fiber optic materials, including glass and polymeric fibers, are suitable for use with the invention.

In addition, in specific implementations the fiber optic material can be tapered in a manner such that it is wider near the LED than near the substrate. Such implementations are advantageous because they promote coupling of light into the fiber from the LED while still focusing the light into a small spot on the substrate. These tapered fibers, also referred to as asymmetric fibers, can have various narrowing profiles. However, they are typically constructed such that they maintain sufficiently parallel surfaces so that internal reflection is maintained. In addition to fiber optics, light guides can include internal reflectors that are not fibers, for example sheets, rods, cones, pyramids, etc. Mirrored surfaces can also function as light guides in various implementations of the invention. The mirrored surfaces can be used so as to conserve and direct the light emitted from the LEDs.

E. LED, Substrate, and Light Guide Movement

In most implementations of the invention a mechanism is included for moving the LEDs, the substrate, or the light guide (or a combination of them) in a manner such that large substrate surfaces can be exposed to light emitted by the LEDs. This movement is necessary in order to provide large, high-resolution photoresist images. If a photoresist image is 8 by 10 inches in size, and will have a resolution of 300 dots per inch, then a total of over seven million different points may be subject to exposure by the LEDs. Without movement of the elements of the system an equal number of LEDs would be required to expose the substrate. Thus, each LED must be able to expose multiple distinct portions of the substrate.

A first implementation for providing relative movement of the light source and the substrate in accordance with the invention is accomplished by moving the LEDs with respect to the substrate. In such implementations the LEDs can be maintained on a moving platform that is capable of being positioned at multiple places over the substrate. During use the LED array travels over the substrate and sequentially exposes portions of the substrate until all desired portions have been exposed.

A second implementation for providing relative movement of the light source and the substrate in accordance with the invention is accomplished by moving the substrate with respect to the LEDs. In such implementations the LEDs are typically stationary but the substrate moves in a fashion that permits the entire substrate to be exposed to the LEDs. Typically such implementations are well suited to broad arrays (such as that depicted in FIGS. 3B and 3C) that allow a substrate to pass over the LED in a single dimension movement (i.e., by being sheet-fed).

Yet another implementation for providing movement includes maintaining the light source and substrate in a stationary position but moving the light guide across the substrate surface. Such implementations are particularly well suited to uses of fiber optics. Alternatively, various combinations of these motions may be used to provide satisfactory coverage of the substrate by light emitted from the LEDs.

F. Substrates

The substrate generally contains a photoreactive composition such as Reflex Films (available from Chromaline Corporation, USA); Capillex films (available from Autotype, England), Kiwofilm DS films (available from KIWO, Germany), Ulano CDF films (available from Ulano, USA), MS films (available from Murakami, Japan), Riston LaserSeries films (available from LDI resist, DuPont, USA), SR2000 films (available from Rayzist, USA), and other film or emulsion products intended for imaging using UV radiation in the range of about 320-470 nm.

G. Methods

The present invention is also directed to methods of exposing a substrate containing a photoreactive composition. The methods generally comprise providing a light emitting device for controlled exposure of photoreactive compositions, the device comprising an apparatus for retaining a photosensitive substrate containing a photoreactive composition; a light emitting diode array containing a plurality of light emitting diodes; and a control mechanism for regulating the intensity and distribution of light emitted from the light emitting diode array; wherein the light emitting diodes are configured and arranged for controlled exposure of the photoreactive composition; providing a substrate containing a photoreactive composition; and exposing the photoresist substrate with light from the light emitting device.

H. Experimental

In order to demonstrate the efficacy of using LEDs to expose photoresist films, a series of tests were performed in which an 18 micron thick Reflex™ film made by Chromaline Corporation of Duluth, Minn. was exposed to various wavelengths of light for specific periods of time and power levels. After exposure the films were washed with warm water (approximately 35 to 40° C.) with mild agitation for approximately three minutes. The results of this test are shown below in Table 1, in which the extent of reaction is qualitatively expressed on a scale of 1 to 7, with 1 being little or no apparent exposure and 7 being significant overexposure.

| | 5 sec. | 10 sec. | 30 sec. | 60 sec. | 180 sec. |
|---|---|---|---|---|---|
| λ (nm) | exp. | exp. | exp. | exp. | exp. |
| 470 | 1 | 1 | 1 | 1 | 1 |
| 389 | 2 | 4 | 5 | 6 | 7 |
| 430 | 1 | 3 | 4 | 6 | 6 |
| 390 | 3 | 3 | NA | 6 | 6 |
| 384 | 4 | 5 | 6 | 6 | 7 |
| 375 | 1 | 1 | 2 | 3 | 4 |
| 384 | 2 | 4 | 4 | 4 | 4 |
| 390 | 4 | 5 | 7 | 7 | 7 |

Exposure key:

1=little or no apparent exposure

2=trace levels of exposure

3=from trace exposure to 25 percent exposure

4=from 25 percent exposure to 50 percent exposure

5=fully exposed

6=fully exposed with slight overexposure

7=significant over exposure

The foregoing description, examples, methods of use and other disclosures in the specification provide a basis for understanding the laminate materials and the operation of the invention. However, since many embodiments of the invention can be made without departing from the spirit or scope of the invention, the invention resides in the claims hereinafter appended.

We claim:

1. A device for controlled exposure of photoreactive compositions, the device comprising:
an apparatus for retaining a photosensitive substrate containing a photoreactive composition;
a light emitting diode array containing a plurality of light emitting diodes; and
a control mechanism for regulating the intensity and distribution of light emitted from the light emitting diode array;
wherein the light emitting diodes are configured and arranged for controlled exposure of the photoreactive composition.

2. The device for controlled exposure of photoreactive compositions of claim 1, wherein the light emitting diodes have emission spectra below 450 nanometers.

3. The device for controlled exposure of photoreactive compositions of claim 1, wherein greater than 80 percent of the emission spectra of the light emitting diodes is from 350 to 400 nanometers.

4. The device for controlled exposure of photoreactive compositions of claim 1, wherein the array of light emitting diodes emits light at a plurality of wavelengths from 390 to 450 nm.

5. The device for controlled exposure of photoreactive compositions of claim 1, wherein the array of light emitting diodes comprises at least two light emitting diodes.

6. The device for controlled exposure of photoreactive compositions of claim 1, further comprising a light guide for directing light from the array of light emitting diodes to the photosensitive substrate.

7. The device for controlled exposure of photoreactive compositions of claim 7, wherein the light guide comprises a plurality of optic fibers.

8. The device for controlled exposure of photoreactive compositions of claim 1, wherein the plurality of optic fibers comprises asymmetric fibers.

9. The device for controlled exposure of photoreactive compositions of claim 8, further comprising a photoresist laminate containing photosensitive compositions sensitive to a plurality of wavelengths of light.

10. The device for controlled exposure of photoreactive compositions of claim 1, wherein the photoreactive composition comprises a photoreactive resin.

11. A method of exposing a substrate containing a photoreactive composition, the method comprising:
providing a light emitting device for controlled exposure of photoreactive compositions, the device comprising an apparatus for retaining a photosensitive substrate containing a photoreactive composition; a light emitting diode array containing a plurality of light emitting diodes; and a control mechanism for regulating the intensity and distribution of light emitted from the light emitting diode array; wherein the light emitting diodes are configured and arranged for controlled exposure of the photoreactive composition;
providing a substrate containing a photoreactive composition; and
exposing the photoresist substrate with light from the light emitting device.

12. The method of exposing a substrate of claim 11, wherein the light emitting diodes have an emission spectra of 350 to 450 nanometers.

13. The method of exposing a substrate of claim 11, wherein greater than 80 percent of the emission spectra of the light emitting diodes is from 350 to 450 nanometers.

14. The method of exposing a substrate of claim 11, wherein the array of light emitting diodes emits light at a plurality of wavelengths from 370 to 430 nanometers.

15. The method of exposing a substrate of claim 14, wherein the array of light emitting diodes comprises diodes that each emit light that is at more than one discrete wavelength band.

16. The method of exposing a substrate of claim 11, further comprising a light guide for directing light from the array of light emitting diodes to the photosensitive substrate.

17. The method of exposing a substrate of claim 11, wherein the light guide comprises a plurality of optic fibers.

18. The method of exposing a substrate of claim 12, wherein the plurality of optic fibers comprises asymmetric fibers.

19. The method of exposing a substrate of claim 11, further comprising a photoresist laminate containing photosensitive compositions sensitive to a plurality of wavelengths of light.

20. The method of exposing a substrate of claim 11, wherein the photoreactive composition comprises a photoreactive resin.
